(19) United States
(12) Patent Application Publication
(10) Pub. No.: US 2010/0319967 A1
(43) Pub. Date: Dec. 23, 2010

(54) INHIBITION OF COPPER DISSOLUTION FOR LEAD-FREE SOLDERING

(75) Inventors: Ahmed Amin, Allentown, PA (US); Mark Adam Bachman, Sinking Spring, PA (US); Frank A. Baiocchi, Allentown, PA (US); John A. Delucca, Wayne, PA (US); John W. Osenbach, Kutztown, PA (US); Zhengpeng Xiong, Singapore (SG)

Correspondence Address: MENDELSOHN, DRUCKER, & ASSOCIATES, P.C., 1500 JOHN F. KENNEDY BLVD., SUITE 405, PHILADELPHIA, PA, 19102, US

(73) Assignee: AGERE SYSTEMS INC., Allentown, PA (US)

(21) Appl. No.: 12/666,437

(22) PCT Filed: Jun. 28, 2007
(86) PCT No.: PCT/US07/72375

§ 371 Date: Dec. 23, 2009

(51) Int. Cl. H05K 1/09; B05D 3/02; C22F 1/08; B23K 31/02; B32B 15/01

(52) U.S. Cl. 174/257; 427/383.7; 148/536; 228/256; 428/647

(57) ABSTRACT

A device fabrication method, according to which a tin-copper-alloy layer is formed adjacent to a copper-plated pad or pin that is used to electrically connect the device to external wiring. Advantageously, the tin-copper-alloy layer inhibits copper dissolution during a solder reflow process because that layer is substantially insoluble in liquid Sn—Ag—Cu (tin-silver-copper) solder alloys under typical solder reflow conditions and therefore shields the copper plating from direct physical contact with the liquefied solder.

### BACKGROUND OF THE INVENTION

1. Field of the Invention

The present invention relates generally to fabrication of electronic devices and, more specifically, to methods of forming interconnect structures for microelectronic packages and circuit boards.

2. Description of the Related Art

Restriction of Hazardous Substances (RoHS) is a European legislation that is aimed at eliminating or severely curtailing the use of cadmium, hexavalent chromium, and lead in virtually all consumer products, from automobiles to microelectronic devices. Many other countries, including the United States, are at various stages of introducing comparable pieces of legislation having similar bans on these substances. RoHS effectively requires electronics manufacturers to replace lead-based terminations on electronic devices and packages with lead-free substitutes.

Tin-silver-copper alloys, also referred to as SAC (short for Sn—Ag—Cu) alloys, are the primary choice for lead-free terminations technology. Although there are other options available, such as alloys containing bismuth, indium, or other elements, tin-silver-copper alloys are by far the most frequently used. For example, a recent survey conducted by Soldertec Global, a membership organization of electronics supply companies, revealed that tin-silver-copper alloys are used by approximately two thirds of manufacturers, and their use is on the rise.

One problem with tin-silver-copper alloys is that, when they are used to solder parts (e.g., contact pads) having copper plating, a tin-silver-copper solder can cause a significant portion of a copper-plating layer to dissolve in the solder during the solder reflow process. Additional description of this problem can be found, e.g., in Chapter 3 of the book entitled “Lead Free Solder Interconnect Reliability”, ed. D. Shangguan, ASM International, Materials Park, Ohio, 2005, the teachings of which are incorporated herein by reference. Although the extent of dissolution depends on the pad's geometry and design and solder-reflow temperature and duration, it is not unusual that more than 25% of the copper plating dissolves during assembly of the package or during component-to-board attachment. Subsequent exposure to field conditions leads to further solder-induced copper consumption via solid-state formation of copper-tin intermetallics. All these processes can disadvantageously compromise integrity and reliability of interconnect structures to a point where the device can no longer meet customer requirements.

### SUMMARY OF THE INVENTION

Problems in the prior art are addressed by various embodiments of a device fabrication method, according to which a tin-copper-alloy layer is formed adjacent to a copper-plated pad or pin that is used to electrically connect the device to external wiring. Advantageously, the tin-copper-alloy layer inhibits copper dissolution during a solder reflow process because that layer is substantially insoluble in liquid Sn—Ag—Cu (tin-silver-copper) solder alloys under typical solder reflow conditions and therefore shields the copper plating from direct physical contact with the liquefied solder.

According to one embodiment, the present invention is a device fabrication method comprising the steps of: (1) providing a device substrate having a copper layer; and (2) forming a tin-copper-alloy layer adjacent to the copper layer to form a layered structure on said substrate.

According to another embodiment, the present invention is a device comprising: (1) a copper layer on a substrate; (2) a tin-copper-alloy layer adjacent to the copper layer, wherein the copper layer and the tin-copper-alloy layer form a layered structure on the substrate; and (3) solder adjacent to the layered structure.

According to yet another embodiment, the present invention is a device comprising: (1) a copper layer; and (2) a tin-copper-alloy layer adjacent to the copper layer, wherein the tin-copper-alloy layer comprises Cu₃Sn.

### BRIEF DESCRIPTION OF THE DRAWINGS

Other aspects, features, and benefits of the present invention will become more fully apparent from the following detailed description, the appended claims, and the accompanying drawings in which:

FIGS. 1A-C schematically show a device fabrication method according to one embodiment of the invention;

FIG. 2 is a quasi-binary phase diagram showing various inter-metallic compounds and phases in a tin-silver-copper poly-metallic system used in the method of FIG. 1;

FIGS. 3-4 show representations of two interconnect structures formed using a typical prior-art fabrication method and an embodiment of the method of FIG. 1, respectively;

FIG. 5 shows a cross-sectional side view of a flip-chip package according to one embodiment of the invention; and

FIG. 6 shows a cross-sectional side view of a circuit board according to one embodiment of the invention.

### DETAILED DESCRIPTION

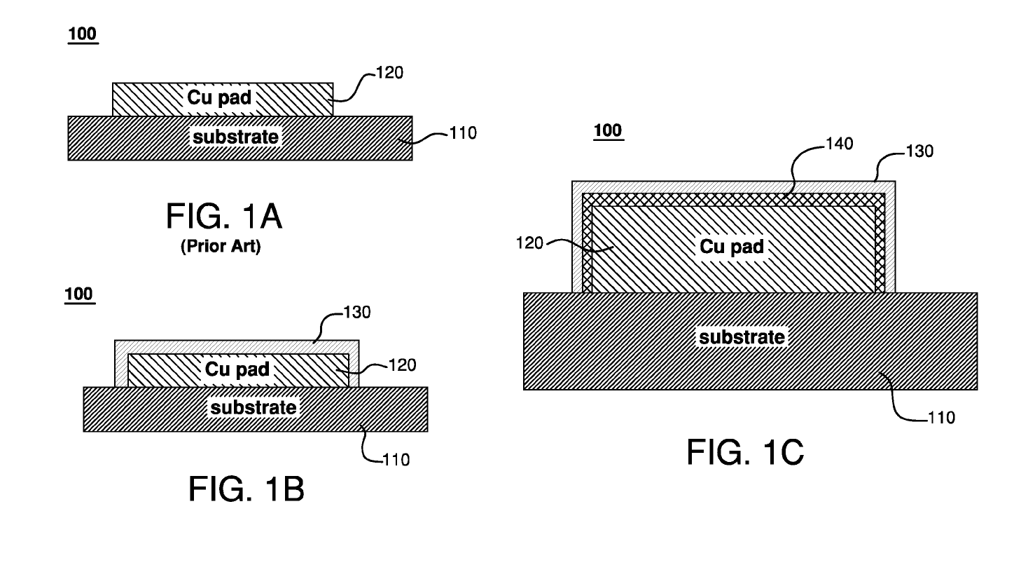

FIGS. 1A-C schematically show a device fabrication method according to one embodiment of the invention. More specifically, each of FIGS. 1A-C shows a cross-sectional view of a device 100 having a copper pad (or layer) 120 that is used to mechanically and/or electrically attach the device to external wiring (not shown in FIG. 1), e.g., an electrical interconnect structure of a circuit board or chip package. In various embodiments, device 100 can be part of a flip-chip package, a ball-grid-array (BGA) package, a circuit board, etc. One skilled in the art will appreciate that various electronic packages, parts, and components, such as copper-lead frame devices, copper heat sinks, and other devices that have copper, solder, and/or tin as part or all of an interconnect structure connecting one part of an electrical circuit to another part of the circuit, can also be fabricated using embodiments of the method of FIG. 1. Further examples of systems suitable for the application of the method of FIG. 1 can be found, e.g., in Chapter 2 of the book entitled “Modern Solder Technology for Competitive Electronics Manufacturing,” by J. S. Hwang, McGraw Hill, New York, New York, 1996, which is incorporated herein by reference. The method of FIG. 1 addresses the above-described copper-dissolution problem by creating a protective barrier 140 around copper pad 120. Advantageously, barrier 140 inhibits the dissolution of copper pad 120 when, during a solder reflow process, the pad is brought into contact with a liquid tin-silver-copper alloy (not shown in FIG. 1).

FIG. 1A shows a cross-sectional view of a portion of device 100 having copper pad 120 formed on a substrate 110. Substrate 110 can, for example, be made of a plastic or ceramic material used for integrated-circuit (IC) packaging or be a semiconductor substrate of the wafer on which the corresponding IC is formed. FIG. 1A also represents a typical structure of a prior-art device.

FIG. 1B shows a cross-sectional view of device 100 after a tin layer 130 is deposited over copper pad 120. In one embodiment, tin layer 130 has a thickness between about 0.1 and 3 μm. Although various thicknesses from this range can be employed, it has been determined that best results are obtained when the thickness of tin layer 130 is between about 0.5 and 1.5 μm, and the thickness of copper pad 120 is at least three times the thickness of tin 130. Tin layer 130 can be formed using chemical vapor deposition, sputtering, electroplating, and/or any other suitable tin deposition technique.

We have discovered a treatment sequence that creates protective barrier 140 in the layered structure of FIG. 1B, which treatment sequence is described in more detail below. The treatment sequence is applied to the layered structure of FIG. 1B prior to further application to the structure of a bulk (volume) of tin or tin-based solder alloys. The treatment sequence causes inter-diffusion and reaction of copper and tin at the interface of copper pad 120 and tin layer 130, thereby forming barrier 140, which is composed of a tin-copper alloy. An important property of this tin-copper alloy is that it is substantially insoluble, under typical solder reflow conditions, in tin-silver-copper or other commonly used lead-free alloys that are commonly used for soldering the above-described electronic packages, parts, and/or components.

One skilled in the art will be able to appropriately modify, without departing from the principles of the present invention, an exemplary soldering process, a brief description of which follows, to adapt it to a specific system at hand. Referring to FIG. 1C, device 100 shown therein can be soldered, for example, as follows. During assembly of the package or board having device 100, the layered structure shown in FIG. 1C is typically placed in contact with a piece (e.g., a ball) of tin-silver-copper alloy (solder). For example, solder balls can be attached to device 100 as known in the art to form a ball grid array. During subsequent solder reflow, the device is heated to a temperature above the melting point of the solder (for typical tin-silver-copper based solders the melting points can range from about 217° C. to about 230° C.) to melt the solder and achieve appropriate wetting of and solder connection to pad 120 and/or substrate 110. At these temperatures, the tin layer dissolves in the liquid solder, thereby exposing barrier 140 to the liquid solder. However, due to the virtual insolubility of the tin-copper alloy of barrier 140 in the liquid tin-silver-copper solder, copper pad 120 remains shielded from direct physical contact with the liquid solder. As a result, substantially none of the material of copper pad 120 is dissolved, which advantageously averts at least some of the problems associated with the unwanted copper dissolution of prior-art fabrication methods.

According to one embodiment, the treatment sequence of the structure shown in FIG. 1B that results in the formation of barrier 140 is performed as follows. First, device 100 of FIG. 1B is optionally heated to a temperature between about 232 and 260° C. to melt tin layer 130. This melting step helps to cover any holes that might be present in layer 130 after the initial formation of that layer. Due to surface wetting, the liquefied tin spreads out, thereby plugging any holes that might be present in layer 130. Next, device 100 is subjected to a thermal anneal process at temperatures between about 125 and 231° C. for a time period between about 0.01 and 48 hours. It has been determined that optimal results are achieved when the annealing process is carried out at about 150° C. for about 1 hour to 7 hours.

Other treatment sequences that can be used to form barrier 140 according to other embodiments of the invention include the following: (1) a treatment having the above-described thermal annealing step only, without the melting step and (2) a treatment sequence having multiple (e.g., between 2 and 10) melting and cooling steps, with or without the above-described thermal annealing step.

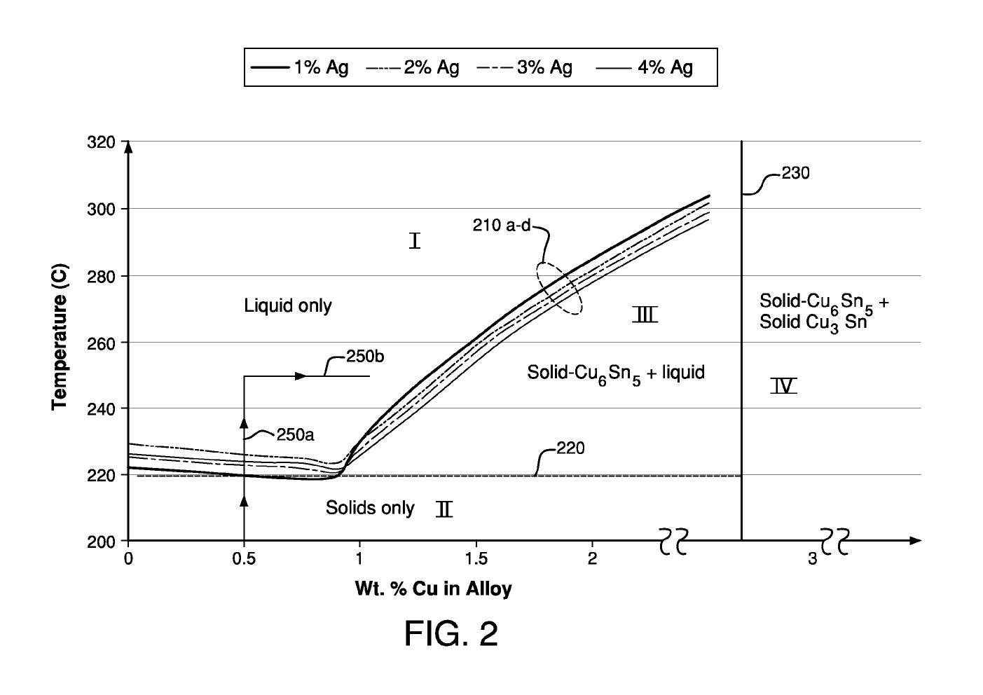

FIG. 2 is a quasi-binary phase diagram showing the liquidus line (above which only a homogeneous liquid exits), the solidous line (below which only solid phases exist), and various copper-tin inter-metallic compounds and phases that exist in a silver-doped tin-copper poly-metallic system for different concentration of silver. Note that the Ag₃Sn solid phase that co-exits in regions II, III, and IV with other phases is not shown in the quasi-binary phase diagram. This omission is intentional, and is made to facilitate (without unduly complicating) the qualitative understanding of the relevant phenomena occurring in the poly-metallic system of FIG. 2, a description of which follows. Without wishing to be bound by any particular theory, we present this quasi-binary phase diagram to graphically illustrate protective properties of barrier 140.

The vertical axis in FIG. 2 represents temperature, and the horizontal axis in the figure represents the weight percentage of copper in the tin-silver-copper alloy (that can contain 1 wt. %, 2 wt. %, 3 wt. %, or 4 wt. % of silver, a typical range of silver content in commonly used SAC alloys). Solid lines 210a-d mark phase boundaries corresponding to various silver contents in the tin-silver-copper alloy (see the legend in FIG. 2). Depending on the exact composition, the liquidus temperature for SAC alloys varies between about 217 and 230° C. A dashed line 220 drawn at about 220° C. marks an approximate location of the liquid-to-solid phase transition for tin-silver-copper alloys, which is helpful for qualitatively understanding the processes occurring in the system of FIG. 2. A solid line 230 marks an approximate location of the phase boundary between a solid tin-copper-alloy phase and a multiphase state, in which solid and liquid phases of the alloy can coexist.

Lines 210, 220, and 230 divide the phase plane of FIG. 2 into four regions, labeled I through IV. In regions I and II, the tin-silver-copper system exists in pure liquid and solid states, respectively. In region III, multiple phases coexist. In particular, a solid tin-copper alloy having a composition of Cu₆Sn₅ coexists with its liquid form in region III. Region IV is a region where two different tin-copper alloys, having the compositions of Cu₆Sn₅ and Cu₃Sn, respectively, can exist in a solid state. Note that solid Cu₃Sn does not exist in region III.

A trace labeled 250 shows a representative phase trajectory for a piece of tin-silver-copper solder having 0.5 wt. % of copper that is heated up from a temperature of 200° C. to a reflow temperature of 250° C., while being in contact with solid copper, e.g., copper pad 120 (see FIG. 1A). Section 250a of trace 250 represents a portion of the phase trajectory on which the temperature is increasing due to the heating. When section 250a crosses the corresponding one of lines 210a-d, the solder liquefies and continues on along the phase trajectory in a liquid state. At the conjunction of sections 250a and 250b, the target temperature of 250° C. is reached, at which point the heating stops and this target temperature is maintained thereafter.

Section 250b of trace 250 depicts a copper dissolution process that takes place at 250° C. More specifically, being in contact with solid copper, the liquid tin-silver-copper solder can and does dissolve the solid copper, which increases the copper content in the solder. This increase can be visualized in FIG. 2 as a gradual drift along section 250b indicated by the corresponding arrow. A substantial amount of copper from the copper pad can be dissolved in the tin-silver-copper solder until the phase trajectory hits the boundary between regions I and III (represented in FIG. 2 by the appropriate one of lines 210a-d). When the liquidus phase boundary is reached, the maximum concentration of copper that can be incorporated into the liquid (solubility limit) is reached, and solid Cu₆Sn₅ begins to precipitate out of solution. At this point in time, the Cu/Cu₆Sn₅/liquid Sn reaction proceeds at a much lower rate via solid-state diffusion, as opposed to the relatively fast liquid-phase dissolution.

In contrast, when a similar piece of tin-silver-copper solder is heated up from 200° C. to 250° C. while in contact with solid Cu₃Sn, the phase trajectory indicated by trace 250 will substantially stop at the end point of section 250a, i.e., the above-described drift along section 250b will not take place. Because solid Cu₃Sn is insoluble in the liquid tin-silver-copper solder, Cu₃Sn has to be converted first into Cu₆Sn₅ before it can be dissolved. While such a conversion can take place because the thermodynamics favor Cu₆Sn₅ over Cu₃Sn, this conversion occurs in a solid state and, as such, is relatively slow. Since a typical reflow process is carried out on a relatively short time scale, there is not enough time for the solid-state reaction to progress far enough to be of any practical significance.

In view of the quasi-binary phase diagram of FIG. 2, it appears that barrier 140 formed as described above is, at least partially, composed of Cu₃Sn. Thus, the deposition of a tin layer over a copper layer followed by one of the above-described treatment sequences that forms a sufficient amount of Cu₃Sn in barrier 140 forms a contiguous protective shield around copper pad 120. Since, as already indicated above, Cu₃Sn is substantially insoluble in a liquid tin-silver-copper solder at typical solder-reflow temperatures, barrier 140 remains intact during the solder-reflow process, which advantageously shields copper pad 120 from direct exposure to liquid tin-silver-copper solder and dissolution therein.

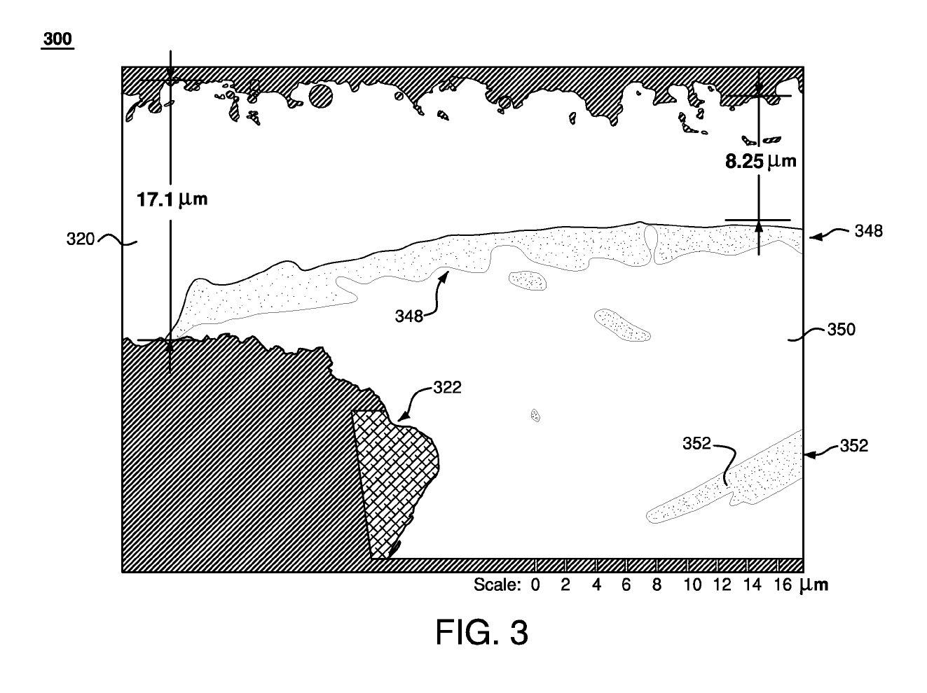

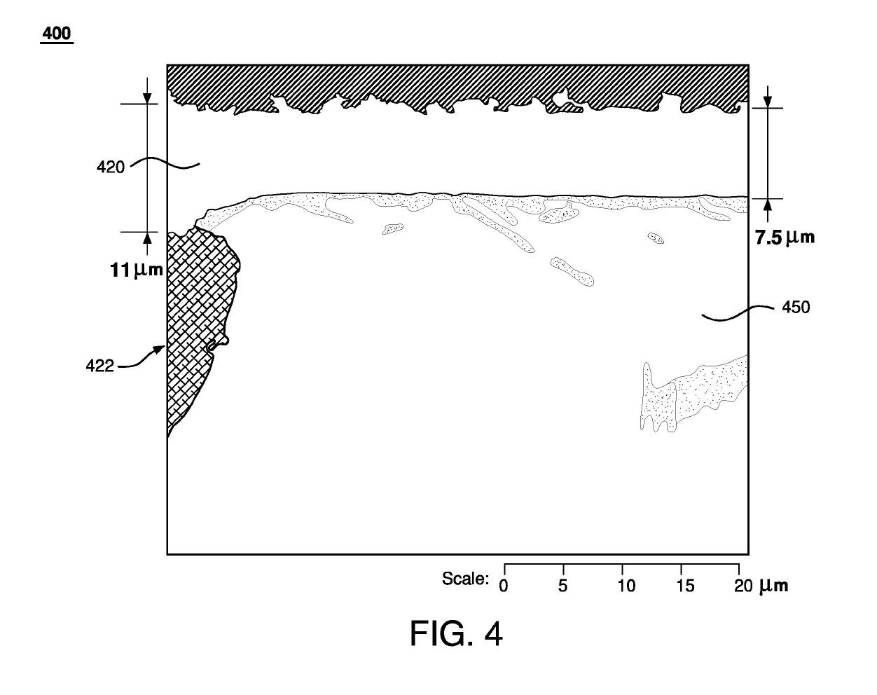

FIGS. 3-4 show representations of two interconnect structures, one formed using a typical prior-art fabrication method and the other formed using an embodiment of the method of FIG. 1, respectively. More specifically, each of FIGS. 3-4 is a rendering of a microphotograph showing a cross-section of the corresponding interconnect structure. Each of the figures is described in more detail below.

Referring first to FIG. 3, an interconnect structure 300 shown therein has a copper pad 320 that is analogous to copper pad 120 of FIG. 1A. The initial thickness of pad 320 is about 17 μm as indicated at the left-hand side of the image. During soldering, only a portion of pad 320 is exposed to the liquid tin-silver-copper solder. More specifically, a solder mask, a part of which is labeled 322 and visible in the image of FIG. 3, protects the left-hand side of pad 320 from exposure to the solder, while leaving the right-hand side of the pad fully exposed. As a result, the thickness of the left-hand side of pad 320 remains substantially unaffected by the processes involved in the formation of interconnect structure 300.

In preparation for solder reflow and attachment, the portion of pad 320 exposed by the solder mask (i.e., the right-hand side of the pad) is chemically treated and etched to ensure good wetting and wicking. This treatment typically causes removal of about 3 μm of copper from the pad prior to soldering. After the preparation, flux is applied to the pad or a tin-silver-copper solder ball or both, followed by placement of the tin-silver-copper solder ball, through an opening in the solder mask, in contact with the treated portion of pad 320. The flux application is optional, but it is typically done to improve the wettability of the solder to pad 320. The resulting structure is then heated to about 250° C. to melt the solder and fuse it with pad 320. During the solder reflow process, pad 320 is in direct physical contact with the liquid tin-silver-copper solder, which causes some of the copper from the pad to dissolve in the solder as described above (see, e.g., trace 250 in FIG. 2). The temperature is then lowered, which causes the tin-silver-copper solder to solidify into a conducting mass 350 that provides electrical contact between pad 320 and external wiring (not shown).

Examination of mass 350 reveals that it is not homogeneous and contains regions having different chemical compositions. In particular, the border region between mass 350 and pad 320 contains a layer 348 composed of Cu₆Sn₅. As already explained in the context of FIG. 2, Cu₆Sn₅ can form during copper dissolution in region III of the phase diagram. Also noticeable is a micro-crystallite 352 composed of Ag₃Sn.

Examination of the thickness of the right-hand side of pad 320 reveals that its final thickness in interconnect structure 300 is about 8 μm. Taking into account the removal of about 3 μm of copper from the exposed portion of pad 320 prior to soldering, one finds that about 6 μm of copper has dissolved in the liquid SAC solder during the solder reflow process. While for relatively thick copper pads, e.g. having a thickness of greater than about 15-20 μm, a 6-μm thickness reduction might still be acceptable, for relatively thin copper pads, e.g., having the initial thickness of smaller than about 15-20 μm, this thickness reduction would cause the pad to become unacceptably thin. A thin copper pad can disadvantageously compromise integrity and reliability of the interconnect structure having that pad and ultimately render that interconnect structure (and thus the whole electronic device) unfit for exposure to certain field conditions, e.g., extreme temperatures.

Referring now to FIG. 4, an interconnect structure 400 shown therein has a copper pad 420 that is analogous to copper pad 120 of FIG. 1. The initial thickness of pad 420 is about 11 μm, as indicated at the left-hand side of the image. Similar to the left-hand side portion of pad 320 in interconnect structure 300, the left-hand side portion of pad 420 in interconnect structure 400 is protected by a solder mask (compare element 322 of FIG. 3 with element 422 of FIG. 4). Therefore, only the right-hand side of pad 420 is exposed to the liquid SAC solder.

In preparation for solder reflow and attachment, the right-hand side of pad 420 is chemically treated and etched, which causes removal of about 3 μm of copper from pad 420. After the treatment, a protective barrier analogous to barrier 140 (see FIG. 1C) is formed over the treated portion of pad 420 using an embodiment of the fabrication method of FIG. 1. After fluxing, a ball of solid tin-silver-copper alloy is then placed, through an opening in the solder mask, in contact with the layers formed over pad 420. The resulting structure is then heated to about 250° C. to melt the solder and fuse it with the structure of pad 420. During the solder reflow process, the protective barrier formed as described above protects pad 420 from direct physical contact with the liquid tin-silver-copper solder, which inhibits copper dissolution. The temperature is then lowered, which causes the tin-silver-copper solder to solidify into a conducting mass 450 that provides electrical contact between pad 420 and external wiring (not shown).

Examination of the thickness of the right-hand side of pad 420 reveals that its final thickness in interconnect structure 400 is about 7.5 μm. Taking into account the removal of about 3 μm of copper from the exposed portion of pad 420 prior to the formation of the protective barrier and some consumption of copper for the formation of the protective barrier itself, the 7.5-μm residual thickness of the pad in interconnect structure 400 is consistent with a conclusion that substantially no copper from the pad has been dissolved in the liquid tin-silver-copper solder during the solder reflow process. For comparison, a prior-art fabrication method similar to that used for the fabrication of interconnect structure 300 would have removed about 6 μm of copper, thereby leaving a residual copper-pad thickness of only about 2 μm. This residual thickness would be too low and most likely unacceptable for structural integrity reasons.

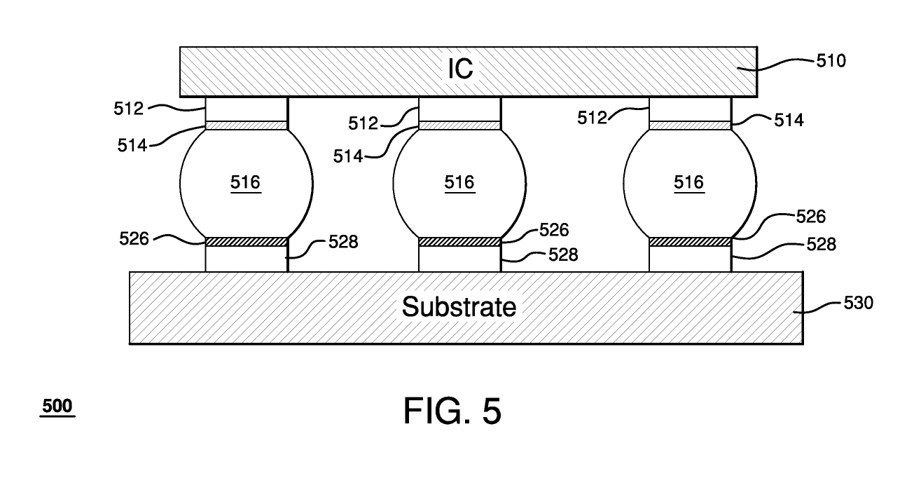

FIG. 5 shows a cross-sectional side view of a flip-chip package 500 according to one embodiment of the invention. Package 500 has an integrated circuit (IC) 510 (also often referred to as a die) connected to a substrate 530 (also often referred to as a carrier). IC 500 has a plurality of metallization pads 512, each typically made of aluminum, titanium, or other suitable metal. Tin-silver-copper solder bumps 516 are attached to pads 512 via a layer 514 made of a suitable intermetallic compound (IMC). Substrate 530 has a plurality of copper metallization pads 528, each of which is analogous to copper pad 120 of FIG. 1. Each pad 528 has a protective barrier 526 formed in accordance with an embodiment of the method illustrated by FIG. 1. During reflow of solder bumps 516, each barrier 526 advantageously protects the respective copper pad 528 from dissolution in the liquefied solder.

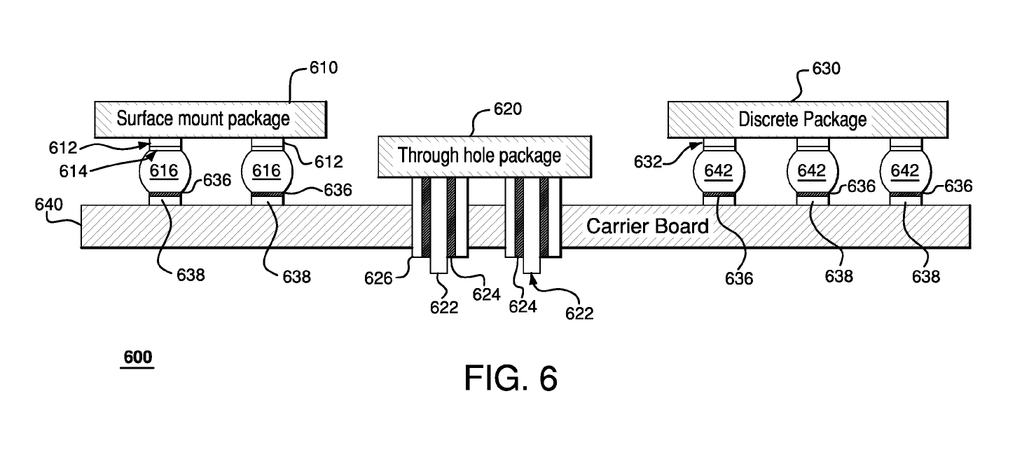

FIG. 6 shows a cross-sectional side view of a circuit board 600 according to one embodiment of the invention. Circuit board 600 has a surface-mount package 610, a through-hole-mount package 620, and a discrete package 630, each connected to a carrier (carrier board) 640. In FIG. 6, packages 610, 620, and 630 are shown after being soldered to carrier board 640. In a representative embodiment, packages 610 and 620 can include respective ICs, and package 630 can be a discrete component, such as a capacitor, resistor, inductor, heat sink, crystal, and connector. Carrier board 640 can be a printed circuit board or a circuit board made using any other suitable method.

Package 610 has a plurality of metallization pads 612, each attached to a respective tin-silver-copper solder ball 616 via a respective IMC layer 614. Carrier board 640 has a plurality of copper metallization pads 638, each of which is analogous to copper pad 120 of FIG. 1. Each pad 638 has a protective barrier 636 formed in accordance with an embodiment of the method illustrated by FIG. 1. During reflow of solder balls 616, barrier 636 advantageously protects the respective copper pad 638 from dissolution in the liquefied solder. In one embodiment, instead of or in addition to metallization pads 612, package 610 can have copper metallization pads with protective barriers analogous to copper metallization pads 638 with barriers 636.

Package 620 has a plurality of pins 622, each having a copper metallization layer (not explicitly shown) and a protective barrier 624 formed in accordance with an embodiment of the method illustrated by FIG. 1. Each pin 622 is inserted into a respective hole in carrier board 640 and connected to the board via a respective tin-silver-copper solder layer 626. During reflow of solder layer 626, barrier 624 advantageously protects the copper metallization layer of respective pin 622 from dissolution in the liquefied solder.

Package 630 is illustratively shown as having pads 632 adapted for surface mounting similar to pads 612 of package 610. Alternatively or in addition, package 630 can have pins (not shown) that are analogous to pins 622. Each pad 632 is connected to the respective pad 638 using a respective solder ball 642. During reflow of solder ball 642, the respective barrier 636 advantageously protects the respective pad 638 from dissolution in the liquefied solder.

In general, circuit board 600 may have: (i) one or more surface-mounted integrated circuits or packages, (ii) one or more through-hole-mounted integrated circuits or packages, (iii) one or more surface-mounted discrete components or packages, and/or (iv) one or more through-hole-mounted discrete components or packages. Pads 638 and solder layers 626 are typically electrically connected to other circuitry located within circuit board 600 and/or external to the circuit board.

While this invention has been described with reference to illustrative embodiments, this description is not intended to be construed in a limiting sense. For example, tin layer 130 of FIG. 1C could be deposited onto any copper-based surface used in the electronics or other industries. With an appropriate treatment sequence disclosed herein, a protective barrier layer can be formed that renders the resulting structure substantially resistant to the adverse effects of solder attachment to the Cu. Such electronic applications include lead-frame packages, heat sinks, circuit boards, various substrates, copper pipes, etc. The protected copper-based parts can be made of pure copper or its alloys, such as brass or other widely used copper alloys. Embodiments of the present invention can be used to create protective barriers for any appropriate soldering applications, e.g., soldering a flip chip to another chip, a carrier, or a circuit board, or soldering a component or package to a circuit board. Various packages and discrete components having protective barriers formed in accordance with embodiments of the present invention can be surface mounted on pads, attached to traces on the circuit board, or through-hole mounted, with hole rims being copper plated and covered by respective protective barriers. Various modifications of the described embodiments, as well as other embodiments of the invention, which are apparent to persons skilled in the art to which the invention pertains are deemed to lie within the principle and scope of the invention as expressed in the following claims.

As used in the specification and claims, the term “adjacent” should be understood as having one or more of the following connotations: immediately preceding or following; located next to; being in close proximity, wherein such proximity may or may not include having a common point, border, or interface.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

It should be understood that the steps of the exemplary methods set forth herein are not necessarily required to be performed in the order described, and the order of the steps of such methods should be understood to be merely exemplary Likewise, additional steps may be included in such methods, and certain steps may be omitted or combined, in methods consistent with various embodiments of the present invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

What is claimed is:

1. A device fabrication method, comprising:
providing a device substrate having a copper layer; and
forming a tin-copper-alloy layer adjacent to the copper layer to form a layered structure on said substrate.

2. The invention of claim 1, wherein the step of forming comprises:
forming a tin layer adjacent to the copper layer; and
subjecting said tin and copper layers to thermal treatment to form the tin-copper-alloy layer at an interface between the tin layer and the copper layer.

3. The invention of claim 2, wherein the step of subjecting comprises:
annealing said tin and copper layers at temperature between about 125° C. and about 231° C. for a time period between about 0.01 and 48 hours.

4. The invention of claim 3, wherein the step of subjecting comprises:
annealing said tin and copper layers at about 150° C. for a time period between about 1 hour and about 7 hours.

5. The invention of claim 3, wherein the step of subjecting further comprises melting and then solidifying the tin layer prior to the annealing.

6. The invention of claim 2, wherein the step of subjecting comprises melting and then solidifying the tin layer.

7. The invention of claim 2, wherein the tin layer has a thickness between about 0.1 μm and about 3 μm.

8. The invention of claim 7, wherein the tin layer has a thickness between about 0.5 μm and about 1.5 μm.

9. The invention of claim 1, wherein the tin-copper-alloy layer comprises Cu₃Sn.

10. The invention of claim 9, wherein the tin-copper-alloy layer consists essentially of Cu₃Sn.

11. The invention of claim 1, further comprising:
reflowing solder positioned adjacent to the layered structure to form an electrical connection between the copper layer and external circuitry.

12. The invention of claim 11, wherein the solder comprises a Sn—Ag—Cu alloy.

13. The invention of claim 11, wherein the tin-copper-alloy layer is substantially insoluble in liquefied solder.

14. A product made using the method of claim 1.

15. A device, comprising:
a copper layer on a substrate; and
a tin-copper-alloy layer adjacent to the copper layer, wherein the copper layer and the tin-copper-alloy layer form a layered structure on said substrate.

16. The invention of claim 15, wherein:
the tin-copper-alloy layer comprises Cu₃Sn;
the copper layer and the tin-copper-alloy layer are part of at least one metallization pad or pin that is adapted to provide an electrical connection between the device and external circuitry; and
the device is an integrated circuit, a discrete circuit component, or a circuit board.

17. The invention of claim 15, further comprising solder adjacent to the layered structure.

18. The invention of claim 17, wherein the solder comprises a Sn—Ag—Cu alloy and is reflowed solder that forms an electrical connection between the copper layer and external circuitry.

19. The invention of claim 17, further comprising:
an integrated circuit soldered to a carrier, wherein a connection between the integrated circuit and the carrier comprises at least one instance of said copper and tin-copper-alloy layers.

20. The invention of claim 17, further comprising:
a circuit component soldered to a circuit board, wherein a connection between the circuit component and the circuit board comprises at least one instance of said copper and tin-copper-alloy layers.
